(19) United States
(12) Patent Application Publication
(10) Pub. No.: US 2002/0125473 A1
(43) Pub. Date: Sep. 12, 2002

(54) Semiconductor device and method of analyzing same

(75) Inventor: Eiji Yoshida, Tokyo (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MITSUBISHI DENKI KABUSHIKI KAISHA, Tokyo (JP)

(21) Appl. No.: 09/931,104

(22) Filed: Aug. 17, 2001

(30) Foreign Application Priority Data
Mar. 6, 2001 (JP) P2001-61638

(51) Int. Cl. H01L 21/00; G01R 31/26; H01L 23/58; H01L 21/66

(52) U.S. Cl. 257/48; 438/11; 438/14; 438/15; 438/18

(57) ABSTRACT

It is an object of the present invention to provide a structure capable of determining a failed part of a semiconductor device in sufficient detail. An n⁺ impurity region (3) and a p⁺ impurity region (4) are connected with each other and further connected with a peripheral circuit (50). A gate electrode (1) and a gate electrode (10) are connected with each other and further connected with the peripheral circuit (50). A ground potential (8) is applied to an n⁺ impurity region (2) and a p⁻ well region (6). A power source potential (9) is applied to a p⁺ impurity region (5) and an n⁻ well region (7). An n⁺ impurity region (23) and a p⁺ impurity region (24) are connected with each other and further connected with the gate electrode (10) through a metal wire (31). The ground potential (8) is applied to a p⁻ well region (26) and the power source potential (9) is applied to an n⁻ well region (27).

### BACKGROUND OF THE INVENTION

1. Field of the Invention

The present invention is directed to a semiconductor device and a method of analysis of the same. More particularly, it is directed to a semiconductor device having a structure realizing easiness in analysis using an LVP (laser voltage probe) technique and a method of analyzing the same.

2. Description of the Background Art

In recent years, rapidity of determination of a failed part has been growingly important in failure analysis techniques of a semiconductor device. In order to determine the failed part of the increasingly large-scale, multilayered and multifunctional semiconductor device, it is necessary to check inner circuit information as well as failure information outputted to an outside of the semiconductor device. Irradiation of a semiconductor element formed on a semiconductor substrate of the semiconductor device with laser beam and electron beam from an upper surface of the semiconductor substrate is one of the ways to check the circuit information inside the semiconductor device.

However, accompanied with a variety of semiconductor devices including LOC (lead on chip), CSP (chip scale package), flip chip and the like, it has been difficult to determine the failed part by irradiation with each beam from the upper surface of the semiconductor substrate. For this reason, the LVP technique for observing fluctuation in potential of an impurity region inside the semiconductor device using a near-infrared laser beam as a probe in a non-contact manner is suggested that has been developed as one of the techniques for analysis of the semiconductor device from a back surface of the semiconductor substrate. When increase in reverse field effect is caused at a pn junction formed between a p-type impurity region and an n-type impurity region, that is, when increase in reverse voltage is caused between the p-type impurity region and the n-type impurity region, absorption of a near-infrared laser beam used for irradiation of the pn junction increases at the pn junction on the basis of Franz-Keldysh effect according to the reverse voltage. As a result, intensity of a light of the laser beam reflected at the pn junction is reduced. According to the LVP technique, change in intensity of the reflected light is detected to thereby observe fluctuation in potential of one of the impurity regions for forming the pn junction. The detailed description of the LVP technique is given in “NOVEL OPTICAL PROBING TECHNIQUE FOR FLIP CHIP PACKAGED MICROPROCESSORS”, Proceedings of the International Test Conference (ITC), pp. 740-747, 1998, for example.

FIG. 11 is a schematic view showing a structure at a section of a semiconductor device in the background art. As shown in FIG. 11, the semiconductor device in the background art has a CMOS transistor 200 including an n channel MOS transistor 110 and a p channel MOS transistor 120.

The n channel MOS transistor 110 includes a gate electrode 1, an n⁺ impurity region 2 acting as a source region and an n⁺ impurity region 3 acting as a drain region. The n⁺ impurity region 2 and the n⁺ impurity region 3 are provided with a certain distance therebetween on a surface of a p⁻ well region 6 formed in a p-type semiconductor substrate 100. The gate electrode 1 is formed above the p⁻ well region 6 through a gate insulating film (not shown) at a position sandwiched between the n⁺ impurity region 2 and the n⁺ impurity region 3.

The p channel MOS transistor 120 includes a gate electrode 10, a p⁺ impurity region 5 acting as a source region and a p⁺ impurity region 4 acting as a drain region. The p⁺ impurity region 5 and the p⁺ impurity region 4 are provided with a certain distance therebetween on a surface of an n⁻ well region 7 formed in the p-type semiconductor substrate 100. The gate electrode 10 is formed above the n⁻ well region 7 through a gate insulating film (not shown) at a position sandwiched between the p⁺ impurity region and the p⁺ impurity region 4.

The n⁺ impurity region 3 and the p⁺ impurity region 4 are connected with each other and further connected with a peripheral circuit 50 through a metal wire 12. The gate electrode 1 and the gate electrode 10 are connected with each other and further connected with the peripheral circuit 50 through a metal wire 11. A ground potential 8 supplied from the outside of the semiconductor device is applied to the n⁺ impurity region 2 and the p⁻ well region 6 through a metal wire 13. A power source potential 9 supplied from the outside of the semiconductor device is applied to the p⁺ impurity region 5 and the n⁻ well region 7 through a metal wire 14.

In the semiconductor device of the background art having the foregoing structure, while the LVP technique allows observation of fluctuation in potential of the drain regions acting as output terminals of the CMOS transistor 200 (the n⁺ impurity region 3 and the p⁺ impurity region 4), observation of fluctuation in potential of the gate electrodes 1, 10 and the source regions (the n⁺ impurity region 3 and the p⁺ impurity region 4) is not realized. As the n⁺ impurity region 2 acting as a source region of the n channel MOS transistor 110 is the same in potential as the p⁻ well region 6, there occurs no reverse voltage to be applied between the n⁺ impurity region 2 and the p⁻ well region 6. For the similar reason, there occurs no reverse voltage to be applied between the p⁺ impurity region 5 and the n⁻ well region 7 of the p channel MOS transistor 120. Therefore, observation of fluctuation in potential of the source regions is not realized by the LVP technique. Further, as the gate electrodes 1 and 10 formed above the p-type semiconductor substrate 100 through the gate insulating film does not form a pn junction, observation of fluctuation in potential of the gate electrodes 1 and 10 is not realized either by the LVP technique.

On the other hand, the n⁺ impurity region 3 acting as a drain region of the n channel MOS 110 transistor outputs the power source potential 9 or outputs the ground potential 8 when switching operation of the CMOS transistor 200 is performed. The p⁻ well region 6 for forming a pn junction together with the n⁺ impurity region 3 is fixed to the ground potential 8. Therefore, when the power source potential 9 is outputted from the CMOS transistor 200, a reverse voltage is applied between the n⁺ impurity region 3 and the p⁻ well region 6. The pn junction formed between the n⁺ impurity region 3 and the p⁻ well region 6 is irradiated with a near-infrared laser beam 20 and intensity of a reflected light of the laser beam 20 is detected. As a result, fluctuation in potential of the n⁺ impurity region 3 can be observed. When the ground potential 8 is outputted from the CMOS transistor 200, fluctuation in potential of the p⁺ impurity region 4 acting as a drain region of the p channel MOS transistor 120 can be observed in a similar way.

There has been a problem that observation of fluctuation in potential of the drain regions acting as output terminals of the CMOS transistor 200 is insufficient to determine a failed part of the semiconductor device. It is necessary to determine in detail whether the cause of failure lies in the n channel MOS transistor 110, in the p channel MOS transistor 120 or in the metal wires 11, 12. When the cause of the failure is in the metal wires 11 and 12, it is further necessary to locate the cause of the failure in the metal wire 11 and 12. Therefore, fluctuation in potential of the gate electrodes 1, 10 acting as input terminals of the CMOS transistor 200 and of the metal layers 11, 12 should be observed. Moreover, in order to determine failure in noise of the power source potential 9 and the ground potential 8, fluctuation in potential of the power source potential 9 and the ground potential 8 should be observed.

### SUMMARY OF THE INVENTION

A first aspect of the present invention is directed to a semiconductor device, comprising: a portion to be measured by fluctuation in potential; a wire having one end and the other end connected with the portion to be measured; and an observation part connected with the one end of the wire, wherein the observation part includes a pn junction irradiated with a laser beam to detect the fluctuation in potential, and the pn includes a first impurity region of a first conductivity type connected with the one end of the wire and a second impurity region of a second conductivity type.

Preferably, in the first aspect, the first impurity region is formed within the second impurity region.

According to a second aspect of the present invention, in the semiconductor device according to the first aspect, the observation part includes a first MOS transistor having the first impurity region as a source/drain region.

According to a third aspect of the present invention, in the semiconductor device according to the second aspect, the first MOS transistor includes a gate electrode set to be the same in potential as the second impurity region.

A fourth aspect of the present invention is directed to the semiconductor device according to the second or third aspect, further comprising a second MOS transistor including the portion to be measured, wherein the first MOS transistor and the second MOS transistor are arranged in a same gate array.

According to a fifth aspect of the present invention, in the semiconductor device according to the fourth aspect, the portion to be measured is a gate electrode of the second MOS transistor.

According to a sixth aspect of the present invention, in the semiconductor device according to the fourth aspect, the portion to be measured is a source/drain region of the second MOS transistor.

According to a seventh aspect of the present invention, in the semiconductor device according to the fourth aspect, the portion to be measured is a well region of the second MOS transistor.

An eighth aspect of the present invention is directed to the semiconductor device according to the first aspect, further comprising a wire to be measured including the portion to be measured.

According to a ninth aspect of the present invention, in the semiconductor device according to the eighth aspect, the observation part includes: a third impurity region connected with a second portion to be measured different from the portion to be measured and made conductive with the wire to be measured; and a fourth impurity region having a conductivity type opposite to a conductivity type of the third impurity region.

According to a tenth aspect of the present invention, in the semiconductor device according to the first aspect, the first conductivity type is an n type an the second conductivity type is a p type; the observation part further includes a second pn junction having a p-type third impurity region connected with the wire and an n-type fourth impurity region; and a first fixed potential is applied to the second impurity region and a second fixed potential higher than the first fixed potential is applied to the fourth impurity region.

An eleventh aspect of the present invention is directed to a method of analyzing the semiconductor device according to the first to eighth aspects, comprising the steps of (a) irradiating the pn junction with a laser beam; and (b) measuring light intensity of the laser beam reflected at the pn junction.

In the semiconductor device according to the first aspect of the present invention, observation of fluctuation in potential of the portion to be measured provided apart from the observation part is allowed at the observation part.

In the semiconductor device according to the second aspect of the present invention, fluctuation in potential of the portion to be measured can be measured at the first MOS transistor.

In the semiconductor device according to the third aspect of the present invention, no switching operation of the first MOS transistor is performed. Therefore, it is possible to measure fluctuation in potential of the portion to be measured with accuracy.

In the semiconductor device according to the fourth aspect of the present invention, observation of fluctuation in potential of the portion to be measured included in the second MOS transistor is allowed at the first MOS transistor.

In the semiconductor device according to the fifth aspect of the present invention, observation of fluctuation in potential of the gate electrode of the second MOS transistor is allowed at the first MOS transistor.

In the semiconductor device according to the sixth aspect of the present invention, observation of fluctuation in potential of the source/drain region of the second MOS transistor is allowed at the first MOS transistor.

In the semiconductor device according to the seventh aspect of the present invention, observation of fluctuation in potential of the well region of the second MOS transistor is allowed at the first MOS transistor.

In the semiconductor device according to the eighth aspect of the present invention, observation of fluctuation in potential of the portion to be measured, included in the wire to be measured provided apart from the observation part, is allowed at the observation part.

In the semiconductor device according to the ninth aspect of the present invention, observation of fluctuation in potential is allowed at the portion to be measured of the wire to be measured and at the second portion to be measured. Therefore, it is possible to determine a failed part in the wire to be measured.

In the semiconductor device according to the tenth aspect of the present invention, two pn junctions of different types are used. Therefore, it is possible to extend the range of observation of fluctuation in potential of the portion to be measured.

In the method of analyzing the semiconductor device according to the eleventh aspect of the present invention, it is possible to analyze the semiconductor device according to the first to eighth aspects of the present invention.

It is therefore an object of the present invention to provide a semiconductor device having a structure capable of determining a failed part of the semiconductor device in detail and a method of analyzing the same.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic view showing a structure at a section of a semiconductor device according to a first preferred embodiment of the present invention;

FIGS. 2 to 4 are schematic views showing structures at a section of a modification of the semiconductor device according to the first preferred embodiment of the present invention;

FIG. 5 is a schematic view showing a structure at a section of a semiconductor device according to a second preferred embodiment of the present invention;

FIG. 6 is a schematic view showing a structure at a section of a modification of the semiconductor device according to the second preferred embodiment of the present invention;

FIG. 7 is a schematic view showing a structure at a section of a semiconductor device according to a third preferred embodiment of the present invention;

FIG. 8 is a plan view schematically showing the structure of the semiconductor device according to the third preferred embodiment of the present invention;

FIGS. 9A, 9B and FIGS. 10A, 10B are schematic views showing structures at a section of a semiconductor device according to a fourth preferred embodiment of the present invention; and

FIG. 11 is a schematic view showing a structure at a section of a semiconductor device in the background art.

### DESCRIPTION OF THE PREFERRED EMBODIMENTS

First Preferred Embodiment

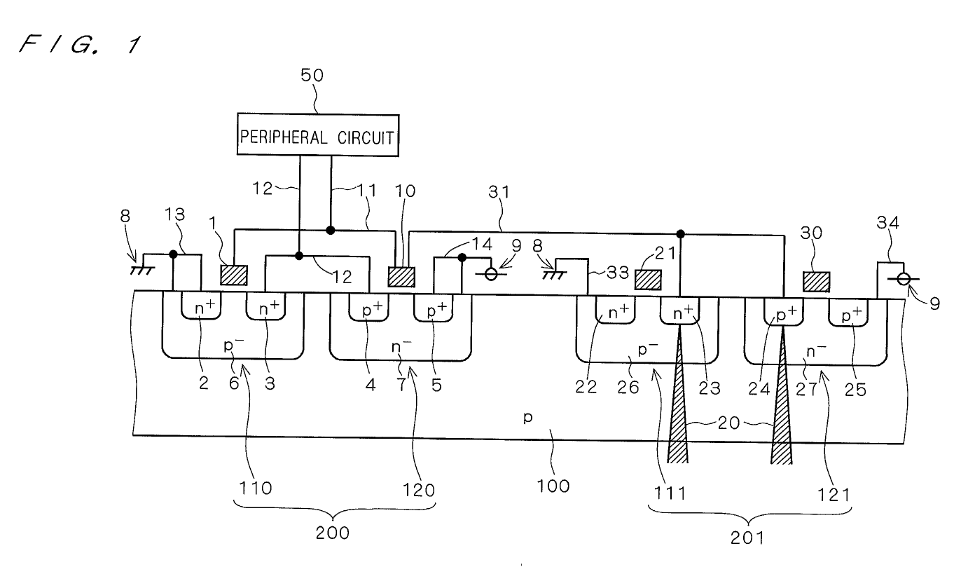

FIG. 1 is a schematic view showing a structure of a semiconductor device according to the first preferred embodiment. The semiconductor device in the background art described above includes a gate array structure, for example, a CMOS transistor 201 normally not to be used for circuit operation (such transistor will be hereinafter referred to as “unused transistor”) is provided in the periphery of the CMOS transistor 200. By using the unused CMOS transistor 201, the semiconductor device according to the first preferred embodiment includes the structure allowing observation of fluctuation in potential of the gate electrodes 1 and 10 of the CMOS transistor 200.

As shown in FIG. 1, the semiconductor device according to the first preferred embodiment has a CMOS transistor 200 including an n channel MOS transistor 110 and a p channel MOS transistor 120 and a CMOS transistor 201 including an n channel MOS transistor 111 and a p channel MOS transistor 121. The CMOS transistor 201 is the unused transistor provided in the periphery of the CMOS transistor 200.

The n channel MOS transistor 110 of the CMOS transistor 200 includes a gate electrode 1, an n⁺ impurity region 2 acting as a source region and an n⁺ impurity region 3 acting as a drain region. The n⁺ impurity region 2 and the n⁺ impurity region 3 are provided with a certain distance therebetween on a surface of a p⁻ well region 6 formed in a p-type semiconductor substrate 100. The gate electrode 1 is formed above the p⁻ well region 6 through a gate insulating film (not shown) at a position sandwiched between the n⁺ impurity region 2 and the n⁺ impurity region 3. The p channel MOS transistor 120 includes a gate electrode 10, a p⁺ impurity region 5 acting as a source region and a p⁺ impurity region 4 acting as a drain region. The p⁺ impurity region 5 and the p⁺ impurity region 4 are provided with a certain distance therebetween on a surface of an n⁻ well region 7 formed in the p-type semiconductor substrate 100. The gate electrode 10 is formed above the n7 well region 7 through a gate insulating film (not shown) at a position sandwiched between the p⁺ impurity region 5 and the p⁺ impurity region 4.

The n channel MOS transistor 111 of the unused CMOS transistor 201 includes a gate electrode 21, an n⁺ impurity region 22 acting as a source region and an n⁺ impurity region 23 acting as a drain region. The n⁺ impurity region 22 and the n⁺ impurity region 23 are provided with a certain distance therebetween on a surface of a p⁻ well region 26 formed in the p-type semiconductor substrate 100. The gate electrode 21 is formed above the p⁻ well region 26 through a gate insulating film (not shown) at a position sandwiched between the n⁺ impurity region 22 and the n⁺ impurity region 23. The p channel MOS transistor 121 includes a gate electrode 30, a p⁺ impurity region 25 acting as a source region and a p⁺ impurity region 24 acting as a drain region. The p⁺ impurity region 25 and the p⁺ impurity region 24 are provided with a certain distance therebetween on a surface of an n⁻ well region 27 formed in the p-type semiconductor substrate 100. The gate electrode 30 is formed above the n⁻ well region 27 through a gate insulating film (not shown) at a position sandwiched between the n⁺ impurity region 25 and the n+impurity region 24.

The n⁺ impurity region 3 and the p⁺ impurity region 4 of the CMOS transistor 200 are connected with each other and further connected with a peripheral circuit 50 through a metal wire 12. The gate electrode 1 and the gate electrode 10 are connected with each other and further connected with the peripheral circuit 50 through a metal wire 11. A ground potential 8 supplied from the outside of the semiconductor device is applied to the n⁺ impurity region 2 and the p⁻ well region 6 through a metal wire 13. A power source potential 9 supplied from the outside of the semiconductor device is applied to the p⁺ impurity region 5 and the n⁻ well region 7 through a metal wire 14.

The n⁺ impurity region 23 and the p⁺ impurity region 24 of the unused CMOS transistor 201 are connected with each other at one end of a metal wire 31. The other end of the metal wire 31 is connected with the gate electrode 10. As the gate electrode 1 and the gate electrode 10 are connected with each other through the metal wire 11, electrical connection is established between the gate electrode 1 and the n⁺ impurity region 23, p⁺ impurity region 24. The ground potential 8 is applied to the p⁻ well region 26 through a metal wire 33 and the power source potential 9 is applied to the n⁻ well region 27 through a metal wire 34.

In the semiconductor device including the foregoing structure according to the first preferred embodiment, various potentials are outputted from the peripheral circuit 50 to the gate electrodes 1 and 10 to perform switching operation of the CMOS transistor 200. As the p⁻ well region 26 is fixed to the ground potential 8, there occurs reverse voltage to be applied between the n⁺ impurity region 23 and the p⁻ well region 26 when these potentials are higher than the ground potential 8. For the similar reason, when these potentials are lower than the power source potential 9, there occurs reverse voltage to be applied between the p⁺ impurity region 24 and the n⁻ well region 27. Especially when the level of such potentials are between those of the ground potential 8 and the power source potential 9, there occurs reverse voltage to be applied between the n⁺ impurity region 23 and the p⁻ well region 26 and further between the p⁺ impurity region 24 and the n⁻ well region 27.

A pn junction formed between the n⁺ impurity region 23 and the p well region 26 or a pn junction formed between the p⁺ impurity region 24 and the n⁻ well region 27 is irradiated with a near-infrared laser beam 20 from a back surface of the p-type semiconductor substrate 100 to detect intensity of a reflected light thereof. The fluctuation in potential of the gate electrodes 1 and 10 is thereby observed. Further, the range of observation of fluctuation in potential can extended by using two types of pn junctions for observation.

In the semiconductor device according to the first preferred embodiment, observation of fluctuation in potential of the gate electrodes 1 and 10 acting as input terminals of the CMOS transistor 200 is realized as well observation of fluctuation in potential of the drain regions (the n⁺ impurity region 3 and the p⁺ impurity region 4) acting as output terminals of the same. As a result, the failed part can be determined more specifically as compared with the semiconductor device in the background art.

The first preferred embodiment describes connection between the drain regions (the n⁺ impurity region 23 and the p⁺ impurity region 24) of the unused CMOS transistor 201 and the gate electrode 10. Alternatively, the gate electrodes 1 and 10 may be connected with the source regions (the n⁺ impurity region 22 and the p⁺ impurity region 25). At this time, a pn junction formed between the n⁺ impurity region 22 and the p⁻ well region 26 or a pn junction formed between the p⁺ impurity region 25 and the n⁻ well region 27 is irradiated, as a matter of course, with the near-infrared laser beam 20. The discrimination between the source region and drain region may not be required in the present invention. The region including either source region or drain region is referred to as “source/drain region” in the present specification and claims when such discrimination is not necessary.

While the first preferred embodiment employs the unused CMOS transistor 201 for observation of fluctuation in potential of the gate electrodes 1 and 10, any semiconductor element including a pn junction is applicable. For example, the gate electrodes 1 and 10 are electrically connected with either a p-type impurity region or an n-type impurity region included in a diode or an n channel MOS transistor. Next, a potential of either one of the p-type impurity region or the n-type impurity region having no connection with the gate electrodes 1 and 10 is fixed to cause reverse voltage to be applied between the p-type impurity region and the n-type impurity region. At this time, when there occurs change in potential of the gate electrodes 1 and 10, reverse electric field of the pn junction is changed in intensity. The pn junction is irradiated with the near-infrared laser beam 20 and intensity of the reflected light thereof is detected, to thereby realize observation of fluctuation in potential of the gate electrodes 1 and 10.

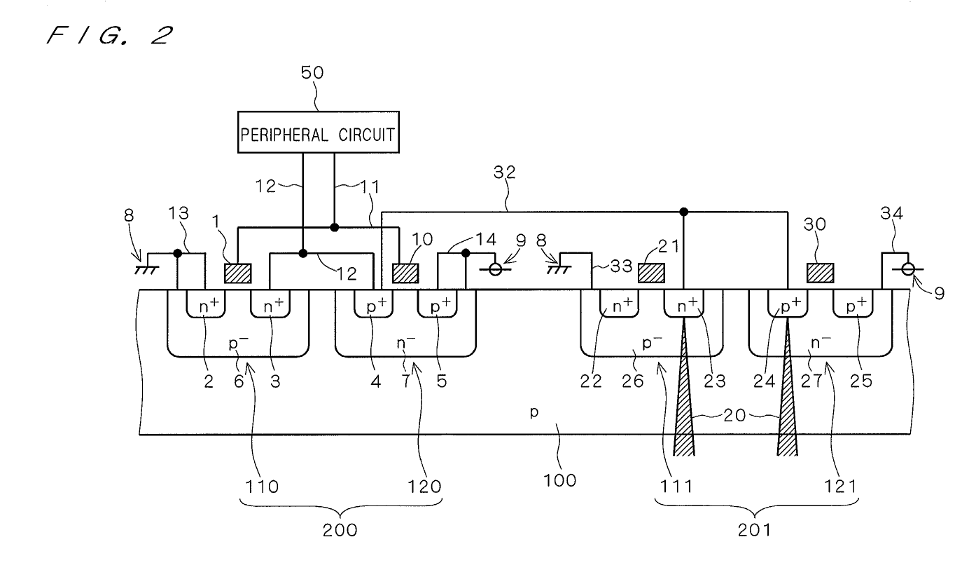

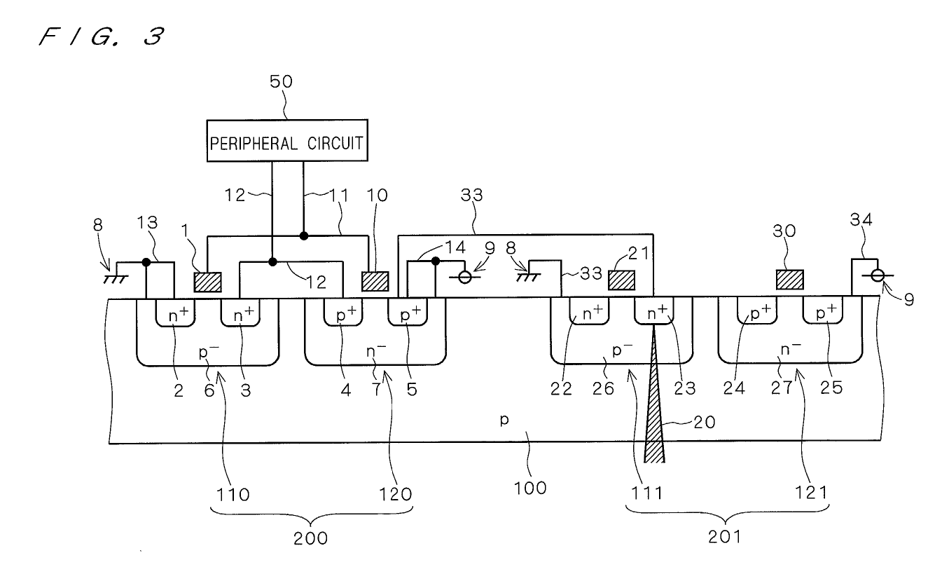

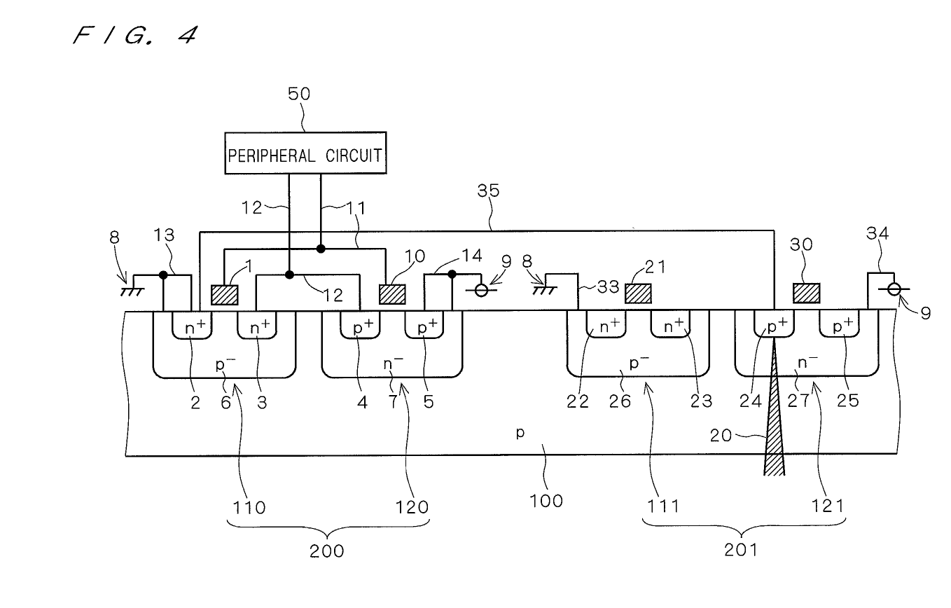

The foregoing describes the example using the pn junction of the unused CMOS transistor 201 to observe fluctuation in potential of the gate electrodes 1 and 10 of the CMOS transistor 200. Fluctuation in potential of the source/drain region of the CMOS transistor 200 can be observed as well. FIGS. 2 to 4 are schematic views showing structures at a section of a modification of the semiconductor device according to the first preferred embodiment. FIG. 2 shows the semiconductor device directed to observation of fluctuation in potential of the drain regions of the CMOS transistor 200. FIG. 3 shows the semiconductor device directed to observation of fluctuation in potential of the source region of the p channel MOS transistor 120. FIG. 4 shows the semiconductor device directed to observation of fluctuation in potential of the source region of the n channel MOS transistor 110.

As shown in FIG. 2, the p⁺ impurity region 4 acting as a drain region of the CMOS transistor 200 and the n⁺ impurity region 23, the p⁺ impurity region 24 of the unused CMOS transistor 201 are connected through a metal wire 32. As already described, when switching operation of the CMOS transistor 200 is performed, the n⁺ impurity region 4 acting as a drain region outputs the power source potential 9 or outputs the ground potential 8. Therefore, there occurs reverse voltage to be applied at least either between the n⁺ impurity region 23 and the p⁻ well region 26 or between the p⁺ impurity region 24 and the n⁻ well region 27. The pn junction formed between the n⁺ impurity region 23 an the p⁻ well region 26 or the pn junction formed between the p⁺ impurity region 24 and the n⁻ well region 27 is irradiated with the near-infrared laser beam 20 and intensity of the reflected light thereof is detected, to thereby realize observation of fluctuation in potential of the drain regions of the CMOS transistor 200.

As shown in FIG. 3, the p⁺ impurity region 5 acting as a source region of the p channel MOS transistor 120 and the n⁺ impurity region 23 of the unused CMOS transistor 201 are connected through the metal wire 33. As the p⁺ impurity region 5 is connected with the power source potential 9, there occurs reverse voltage to be applied between the n⁺ impurity region 23 and the p⁻ well region 26. The pn junction formed between the n⁺ impurity region 23 and the p⁻ well region 26 is irradiated with the near-infrared laser beam 20 and intensity of the reflected light thereof is detected, to thereby realize observation of fluctuation in potential of the p⁺ impurity region 5 acting as a source region of the p channel MOS transistor 120.

As shown in FIG. 4, the n⁺ impurity region 2 acting as a source region of the n channel MOS transistor 110 and the p⁺ impurity region 24 of the unused CMOS transistor 201 are connected through a metal wire 35. As the n⁺ impurity region 2 is connected with the ground potential 8, there occurs reverse voltage to be applied between the p⁺ impurity region 24 and the n⁻ well region 27. The pn junction formed between the p⁺ impurity region 24 and the n⁻ well region 27 is irradiated with the near-infrared laser beam 20 and intensity of the reflected light thereof is detected, to thereby realize observation of fluctuation in potential of the n⁺ impurity region 2 acting as a source region of the n channel MOS transistor 110.

Second Preferred Embodiment

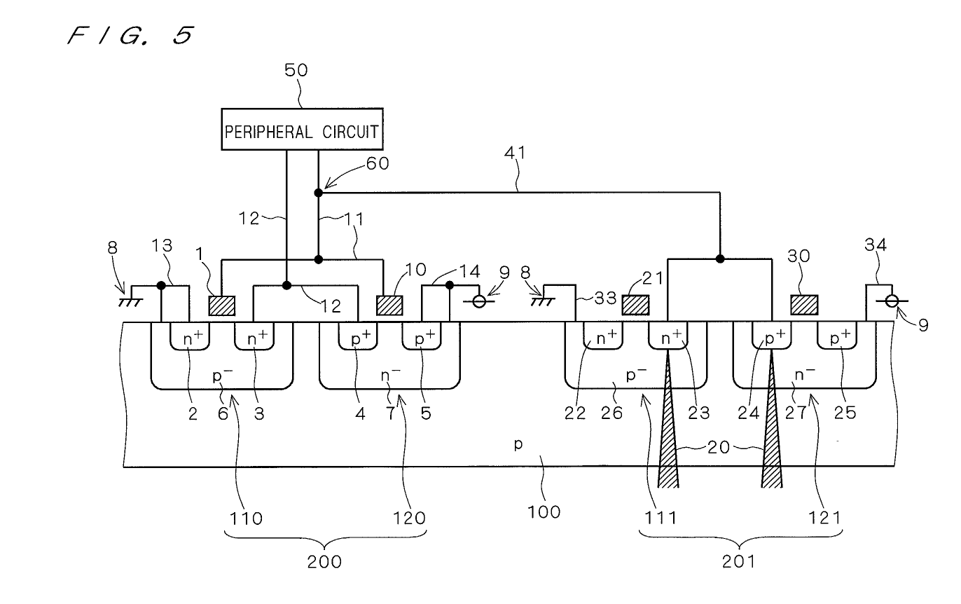

FIG. 5 is a schematic view showing a structure at a section of a semiconductor device according to the second preferred embodiment. As shown in FIG. 5, the second preferred embodiment is directed to the semiconductor device including a metal wire 41 instead of the metal wire 31 in the semiconductor device according to the first preferred embodiment. The metal wire 41 has one end for connecting the n⁺ impurity region 23 and the p⁺ impurity region 24 of the unused CMOS transistor 201 and the other end connected with a connection point 60. As the other configurations of the semiconductor device according to the second preferred embodiment are the same as those of the semiconductor device according to the first preferred embodiment, the description thereof is omitted here.

In the semiconductor device according to the second preferred embodiment having the foregoing structure, as the metal wire 11 is electrically connected with the n⁺ impurity region 23 and the p⁺ impurity region 24, observation of fluctuation in potential of the metal wire 11 is realized. More particularly, the pn junction formed between the n⁺ impurity region 23 and the p⁻ well region 26 or the pn junction formed between the p⁺ impurity region 24 and the n⁻ well region 27 is irradiated with the near-infrared laser beam 20 from the back surface of the p-type semiconductor substrate 100 and intensity of the reflected light thereof is detected, to thereby realize observation of fluctuation in potential of the metal wire 11.

The semiconductor device according to the first preferred embodiment shown in FIG. 1 realizes observation of fluctuation in potential of the gate electrodes 1 and 10. That is, the potential supplied from the peripheral circuit 50 to the gate electrodes 1 and 10 is observed at the ends of the gate terminals 1 and 10. For this reason, when there is a high probability of failure in the metal wire 11, it is difficult to determine the failed parts in the metal wire 11 by observing fluctuation in potential of the gate electrodes 1 and 10. In contrast, as the second preferred embodiment realizes observation of fluctuation in potential of the metal wire 11, it is possible to calculate the failed part in the metal wire 11. More particularly, when change in potential of the metal wire 11 is not observed by the LVP technique at the connection point 60, it is speculated that there occurs failure in the metal wire 11 between the peripheral circuit 50 and the connection point 60.

As mentioned above, the example is given in the second preferred embodiment which is directed to observation in potential of the metal wire 11. By providing the connection point 60 to the metal wire 12, it is further possible to calculate the failed part in the wire between the peripheral circuit 50 and the drain regions of the CMOS transistor 200

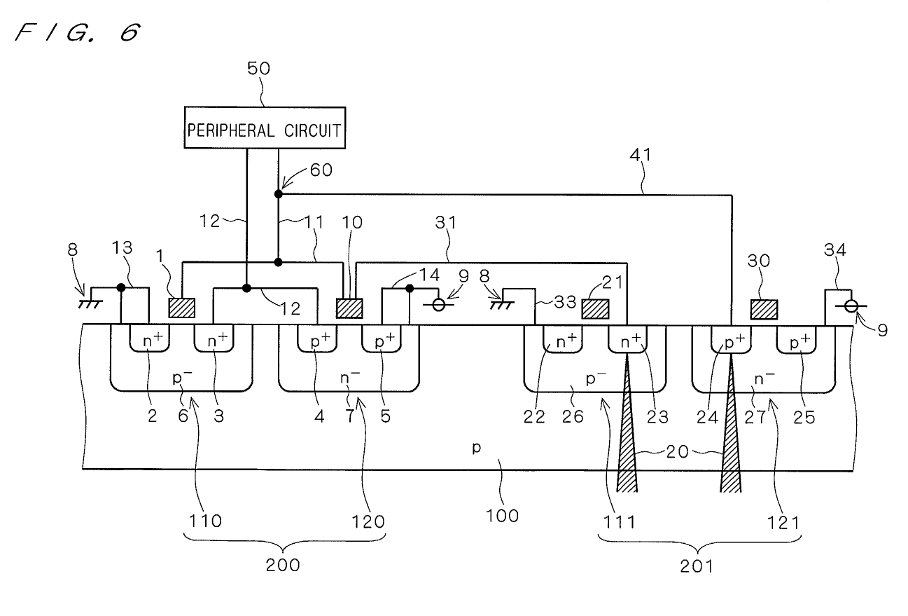

FIG. 6 is a schematic view showing a structure at a section of a modification of the semiconductor device according to the second preferred embodiment. As shown in FIG. 6, the metal wire 31 included in the semiconductor device of the first preferred embodiment shown in FIG. 1 is added to the semiconductor device according to the second preferred embodiment to form the modification thereof. That is, the semiconductor device according to the modification of the second preferred embodiment realizes observation of fluctuation in potential of the gate electrodes 1, 10 and the metal wire 11. More particularly, the gate electrode 10 and the n⁺ impurity region 23 are connected through the metal wire 31. The metal wire 11 and the p⁺ impurity region 24 are connected at the connection point 60 through the metal wire 41. As the other configurations of the semiconductor device shown in FIG. 6 are the same as those of the semiconductor device according to the second preferred embodiment in FIG. 5, the -description thereof is omitted here.

In the semiconductor device shown in FIG. 6 having the foregoing structure, as fluctuation in potential of the gate electrodes 1, 10 and the metal wire 11 is observed, the failed part in the metal wire 11 can be determined more particularly as compared with the semiconductor device shown in FIG. 5. When change in potential of the metal wire 11 is not observed by the LVP technique at the connection point 60, for example, it is speculated that there occurs failure in the metal wire 11 between the peripheral circuit 50 and the connection point 60. Further, when change in potential of the metal wire 11 is observed at the connection 60 but change in potential of the gate electrodes 1 and 10 is not observed, for example, it is speculated that there occurs failure in the metal wire 11 between the connection point 60 and the gate electrodes 1, 10.

Third Preferred Embodiment

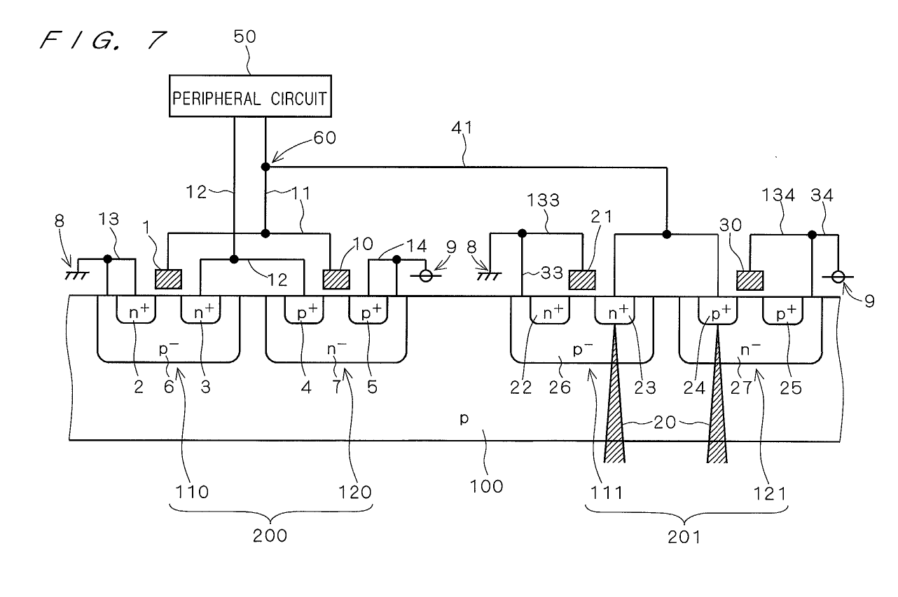

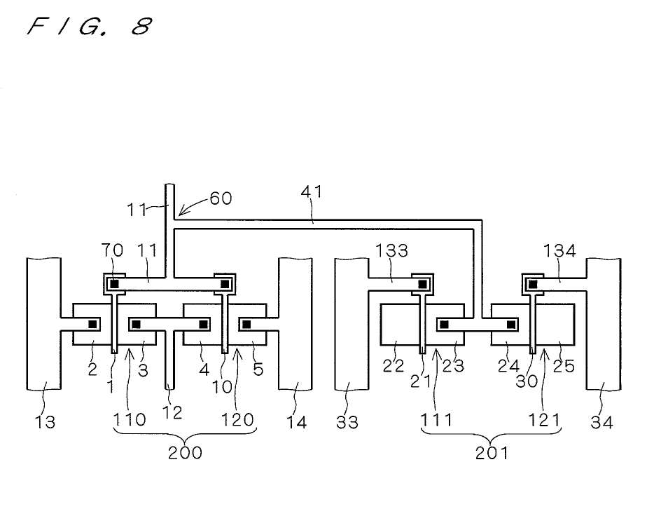

FIG. 7 is a schematic view showing a structure at a section of a semiconductor device according to the third preferred embodiment. FIG. 8 is a plan view schematically showing the structure of the semiconductor device in FIG. 7. The p⁻ well regions 6, 26 and the n⁻ well regions 7, 27 shown in FIG. 7 are omitted from FIG. 8.

As shown in FIGS. 7 and 8, metal wires 133 and 134 are added to the semiconductor device of the second preferred embodiment shown in FIG. 5 to form the semiconductor device according to the third preferred embodiment. More particularly, connection is established between the metal wire 133 connected with the gate electrode 21 and the metal wire 33, to thereby fix the gate electrode 21 to the ground potential 8. Further, connection is established between the metal wire 134 connected with the gate electrode 30 and the metal wire 34, to thereby fix the gate electrode 30 to the power source potential 9. As the other configurations of the semiconductor device according to the third preferred embodiment are the same as those of the semiconductor device according to the second preferred embodiment shown in FIG. 5, the description thereof is omitted here.

In the semiconductor device according to the third preferred embodiment having the foregoing structure, the gate electrode 21 and the p⁻ well region 26 are the same in potential with each other. Further, the gate electrode 30 and the n⁻ well region 27 are the same in potential with each other. Therefore, there occurs no switching operation of the unused CMOS transistor 201 when fluctuation in potential of the metal wire 11 is observed. As a result, observation of fluctuation in potential of the metal wire 11 can be performed with accuracy higher than that of the semiconductor device according to the second preferred embodiment.

The same effect as in the third preferred embodiment can be achieved, as a matter of course, by fixing the gate electrode 21 and the gate electrode 30 in the semiconductor device shown in FIGS. 1 to 4 and FIG. 6 to the ground potential 8 and the power source potential 9.

Fourth Preferred Embodiment

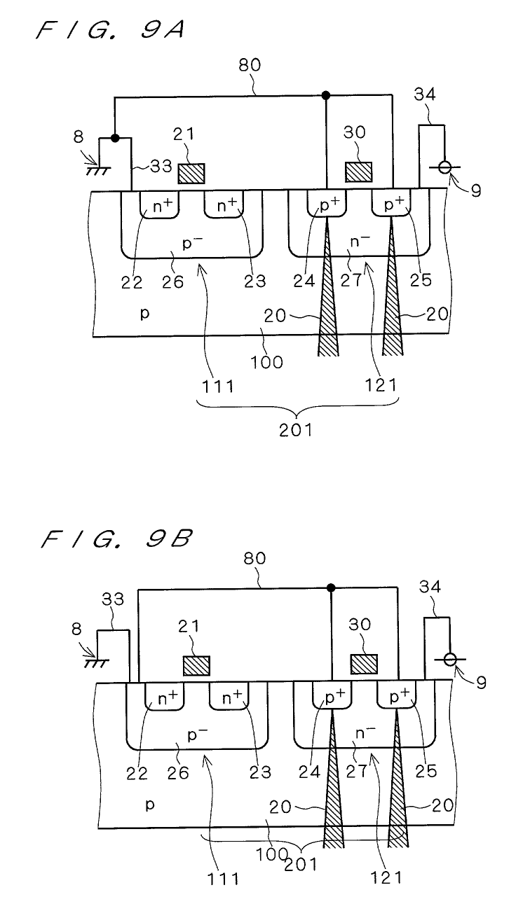

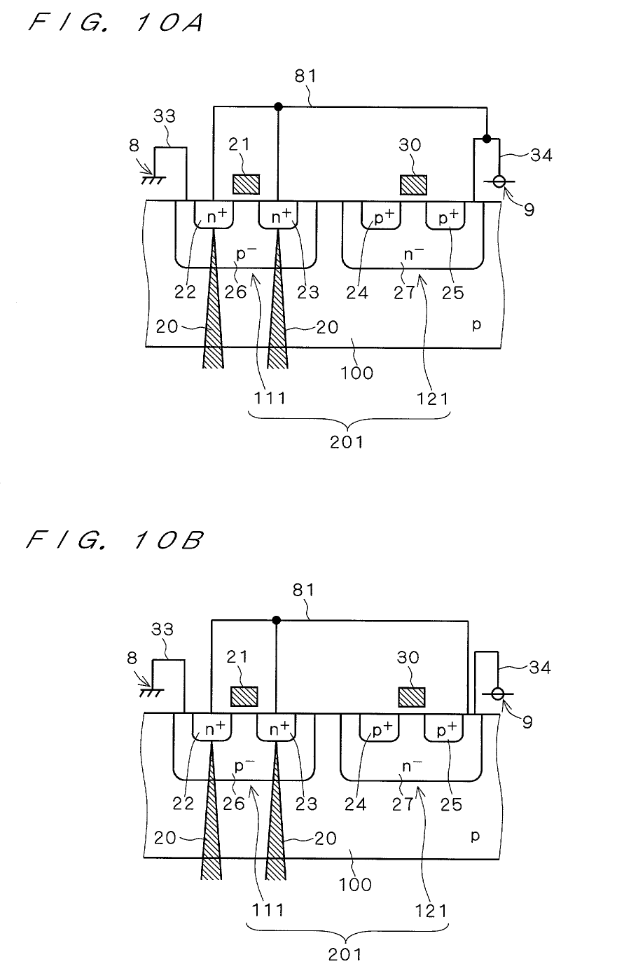

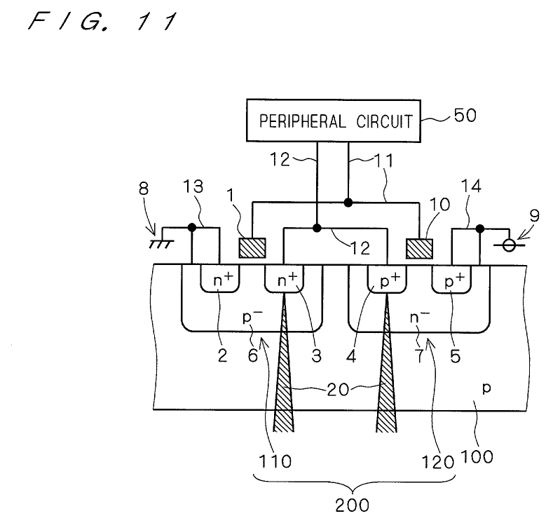

FIGS. 9A, 9B and 10A, 10B are schematic views showing structures of a semiconductor device according to the fourth preferred embodiment. In the semiconductor device according to the fourth preferred embodiment, only the unused CMOS transistor 201 is used for observation of fluctuation in potential difference between the power source potential 9 and the ground potential 8 of the semiconductor device.

In the semiconductor device shown in FIG. 9A, connection is established between a metal wire 80 connected with the p⁺ impurity regions 24, 25 and the metal wire 33, to thereby observe fluctuation in potential of the ground potential 8. More particularly, the p⁻ well region 26 of the unused CMOS transistor 201 is fixed to the ground potential 8 through the metal wire 33 and the n⁻ well region 27 is fixed to the power source potential 9 through the metal wire 34. As the metal wire 80 having connection with the p⁺ impurity regions 24 and 25 is connected with the metal wire 33, connection is established between the p⁺ impurity regions 24, 25 and the ground potential 8. A pn junction formed between the p⁺ impurity regions 24, 25 and the n⁻ well region 27 is irradiated with the near-infrared laser beam 20 and intensity of the reflected light thereof is detected.

In the semiconductor device shown in FIG. 9B, the metal wire 80 having connection with the p⁺ impurity regions 24 and 25 is directly connected with the p⁻ well region 26. Similar to the semiconductor device shown in FIG. 9A, intensity of the reflected light of the near-infrared laser beam 20 is detected accordingly. Here, as the p⁺ impurity regions 24, 25 and the n⁻ well region 27 for forming the pn junction are connected with the ground potential 8 and the power source potential 9, respectively, observation of intensity of the reflected light using the LVP technique means observation of fluctuation in potential difference between the power source potential 9 and the ground potential 8, namely, observation of failure in noise at the power source and failure in fluctuation of a power source voltage of the semiconductor device.

In the semiconductor device shown in FIG. 10A, a metal wire 81 having connection with the n⁺ impurity regions 22 and 23 is connected with the metal wire 34, to thereby observe fluctuation in potential of the power source potential 9. More particularly, the p⁻ well region 26 of the unused CMOS transistor 201 is fixed to the ground potential 8 through the metal wire 33 and the n⁻ well region 27 is fixed to the power source potential 9 through the metal wire 34. As the metal wire 81 having connection with the n⁺ impurity regions 22 and 23 is connected with the metal wire 34, connection is established between the n⁺ impurity regions 22, 23 and the power source potential 9. A pn junction formed between the n⁺ impurity regions 22, 23 and the p⁻ well region 26 is irradiated with the near-infrared laser beam 20 and intensity of the reflected light thereof is detected.

In the semiconductor device shown in FIG. 10B, the metal wire 81 having connection with the n⁺ impurity regions 22 and 23 is directly connected with the n⁻ well region 27. Similar to the semiconductor device shown in FIG. 10A, intensity of the reflected light of the near-infrared laser beam 20 is detected accordingly. Here, as the p⁺ impurity regions 22, 23 and the p⁻ well region 26 for forming the pn junction are connected with the power source potential 9 and the ground potential 8, respectively, observation of intensity of the reflected light using the LVP technique means observation of fluctuation in potential difference between the power source potential 9 and the ground potential 8, namely, observation of failure in noise at the power source and failure in fluctuation of the power source voltage of the semiconductor device.

The p⁻ well region 26 and the n well region 27 of the unused CMOS transistor 201 in a gate array structure are normally connected with the ground potential 8 and the power source potential 9, respectively. Therefore, only the unused CMOS transistor 201 is required as described above to realize observation of failure in noise at the power source and failure in fluctuation of the power source voltage of the semiconductor device.

The semiconductor devices shown in FIGS. 9A and 10A are directed, in other words, to observation of fluctuation in potential of the metal wire 33 and the metal wire 34 for observing failure in noise at the power source of the semiconductor device, for example. Further, the semiconductor devices shown in FIGS. 9B and 10B are directed, in other words, to observation of fluctuation in potential of the p⁻ well region 26 and the n⁻ well region 27 of the unused CMOS transistor 201 for observing failure in noise at the power source of the semiconductor device, for example.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device, comprising:
a portion to be measured by fluctuation in potential;
a wire having one end and the other end connected with said portion to be measured; and
an observation part connected with said one end of said wire,
wherein said observation part includes a pn junction irradiated with a laser beam to detect said fluctuation in potential, and
said pn junction includes a first impurity region of a first conductivity type connected with said one end of said wire and a second impurity region of a second conductivity type.

2. The semiconductor device according to claim 1, wherein said first impurity region is formed within said second impurity region.

3. The semiconductor device according to claim 2, wherein said observation part includes a first MOS transistor having said first impurity region as a source/drain region.

4. The semiconductor device according to claim 3, wherein said first MOS transistor includes a gate electrode set to be the same in potential as said second impurity region.

5. The semiconductor device according to claim 3, further comprising a second MOS transistor including said portion to be measured,
wherein said first MOS transistor and said second MOS transistor are arranged in a same gate array.

6. The semiconductor device according to claim 5, wherein said portion to be measured is a gate electrode of said second MOS transistor.

7. The semiconductor device according to claim 5, wherein said portion to be measured is a source/drain region of said second MOS transistor.

8. The semiconductor device according to claim 5, wherein said portion to be measured is a well region of said second MOS transistor.

9. The semiconductor device according to claim 1, further comprising a wire to be measured including said portion to be measured.

10. The semiconductor device according to claim 9, wherein said observation part includes:
a third impurity region connected with a second portion to be measured different from said portion to be measured and made conductive with said wire to be measured; and
a fourth impurity region having a conductivity type opposite to a conductivity type of said third impurity region.

11. The semiconductor device according to claim 1, wherein
said first conductivity type is an n type and said second conductivity type is a p type;
said observation part further includes a second pn junction having a p-type third impurity region connected with said wire and an n-type fourth impurity region; and
a first fixed potential is applied to said second impurity region and a second fixed potential higher than said first fixed potential is applied to said fourth impurity region.

12. A method of analyzing the semiconductor device recited in claim 1, comprising the steps of:
(a) irradiating said pn junction with a laser beam; and
(b) measuring light intensity of said laser beam reflected at said pn junction.

13. A method of analyzing the semiconductor device recited in claim 2, comprising the steps of:
(a) irradiating said pn junction with a laser beam; and
(b) measuring light intensity of said laser beam reflected at said pn junction.

14. A method of analyzing the semiconductor device recited in claim 3, comprising the steps of:
(a) irradiating said pn junction with a laser beam; and
(b) measuring light intensity of said laser beam reflected at said pn junction.

15. A method of analyzing the semiconductor device recited in claim 4, comprising the steps of:
(a) irradiating said pn junction with a laser beam; and
(b) measuring light intensity of said laser beam reflected at said pn junction.

16. A method of analyzing the semiconductor device recited in claim 5, comprising the steps of:
(a) irradiating said pn junction with a laser beam; and
(b) measuring light intensity of said laser beam reflected at said pn junction.

17. A method of analyzing the semiconductor device recited in claim 6, comprising the steps of:
(a) irradiating said pn junction with a laser beam; and
(b) measuring light intensity of said laser beam reflected at said pn junction.

18. A method of analyzing the semiconductor device recited in claim 7, comprising the steps of:
(a) irradiating said pn junction with a laser beam; and
(b) measuring light intensity of said laser beam reflected at said pn junction.

19. A method of analyzing the semiconductor device recited in claim 8, comprising the steps of:
(a) irradiating said pn junction with a laser beam; and
(b) measuring light intensity of said laser beam reflected at said pn junction.

20. A method of analyzing the semiconductor device3 recited in claim 9, comprising the steps of:
(a) irradiating said pn junction with a laser beam; and
(b) measuring light intensity of said laser beam reflected at said pn junction.
